(19) United States
(12) Patent Application Publication
(10) Pub. No.: US 2025/0336640 A1
(43) Pub. Date: Oct. 30, 2025

(54) ILLUMINATION LENS ADJUSTMENT METHOD, MULTIPLE CHARGED PARTICLE BEAM WRITING APPARATUS, AND STORAGE MEDIUM

(71) Applicant: NuFlare Technology, Inc., Yokohama-shi (JP)

(72) Inventors: Eikai HAYASAKA, Yokohama-shi (JP); Tsubasa NANAO, Yokohama-shi (JP)

(73) Assignee: NuFlare Technology, Inc., Yokohama-shi (JP)

(21) Appl. No.: 19/173,102

(22) Filed: Apr. 8, 2025

(30) Foreign Application Priority Data
Apr. 26, 2024 (JP) 2024-072283

(51) Int. Cl. H01J 37/244; H01J 37/04; H01J 37/10; H01J 37/317

(52) U.S. Cl. CPC H01J 37/244; H01J 37/045; H01J 37/10; H01J 37/3177; H01J 2237/0435; H01J 2237/1502; H01J 2237/24564; H01J 2237/24578

(57) ABSTRACT

An illumination lens adjustment method includes setting variably a lens value of an illumination lens that leads multiple charged particle beams to a blanking aperture array mechanism, where a plurality of openings are formed, which individually performs blanking control for each beam of the multiple charged particle beams passing through the plurality of openings, measuring a maximum movement amount for each lens value from a reference positional relationship, while relatively moving a positional relationship between the multiple charged particle beams and the plurality of openings from the reference positional relationship in a range where a total current amount of beams passing through the plurality of openings for each positional relationship is not less than a threshold, and determining, using the maximum movement amount measured for each lens value, the lens value of the illumination lens and outputting the lens value determined.

### CROSS-REFERENCE TO RELATED APPLICATION

This application is based upon and claims the benefit of priority from prior Japanese Patent Application No. 2024-072283 filed on Apr. 26, 2024 in Japan, the entire contents of which are incorporated herein by reference.

### BACKGROUND OF THE INVENTION

### Field of the Invention

Embodiments of the present invention relate to an illumination lens adjustment method, a multiple charged particle beam writing apparatus, and a non-transitory computer-readable storage medium storing a program thereon. For example, embodiments relate to a method for adjusting an illumination lens in multiple beam writing.

### Description of Related Art

The lithography technique which advances miniaturization of semiconductor devices is extremely important as a unique process whereby patterns are formed in semiconductor manufacturing. In recent years, with high integration of LSI, the line width (critical dimension) necessary for semiconductor device circuits is becoming increasingly narrower year by year. The electron beam writing technique, which intrinsically has excellent resolution, is used for writing or “drawing” patterns on a wafer and the like with electron beams.

For example, as a known example of employing the electron beam writing technique, there is a writing apparatus using multiple beams. Since writing with multiple beams can apply a lot of beams at a time, the writing throughput can be greatly increased compared to writing with a single electron beam. For example, a writing apparatus employing the multiple beam system forms multiple beams by letting an electron beam emitted from an electron gun pass through a mask having a plurality of holes, performs blanking control for each beam, reduces each unblocked beam to generate a reduced mask image by an optical system, and deflects, by a deflector, a reduced beam to be applied to a desired position on a target object or “sample”.

In multiple beam writing, writing is performed while multiple beams are individually blanking controlled. Accordingly, there is arranged a blanking control mechanism which individually performs blanking control of the multiple beams. Therefore, beams to be used for writing are the beams having passed through the blanking control mechanism. In order to reduce the writing time, a beam of a larger current amount is needed. The amount of current is affected by the illumination system lens which leads multiple beams to the blanking control mechanism. Conventionally, a lens value at which the total current amount of the multiple beams having passed through the blanking control mechanism is maximum is set as the lens value of the illumination system lens. However, it has turned out that, according to the method described above, the current density distribution may not be optimized. Furthermore, it has turned out that irregularity of an output angle remains in some beams. Consequently, it causes a problem that local phenomena occur, such as local beam distortion of a beam array on a target object surface, beam blur, and/or positional deviation. Therefore, it becomes necessary to improve a current density distribution, and to reduce local beam distortion, beam blur, and/or position deviation.

There is disclosed a method in which two aperture sets are arranged, the spot diameter of each beam of multiple beams can be selected by changing the positional relationship between the two aperture sets on the assumption that electron beams enter vertically (perpendicularly), and the two aperture sets providing a selected spot diameter are aligned so that the current value may become maximum (e.g., refer to Japanese Patent Application Laid-open (JP-A) No. 2011-171713). However, there is no disclosure on a positional relationship, which changes depending on a lens value, between generated multiple beams and the blanking control mechanism. In addition, another method is disclosed where some beams in multiple beams are made to be on-state in order to scan over a blanking aperture array, and then, a current amount map is generated based on a beam current detection result by a detector and a position of the blanking aperture array, so that multiple beams are let to pass through the blanking aperture array due to adjustment of the position of the blanking aperture array, based on the current amount map for each on-state beam (e.g., refer to Japanese Patent Application Laid-open|(JP-A) No. 2019-121730).

### BRIEF SUMMARY OF THE INVENTION

According to one aspect of the present invention, an illumination lens adjustment method includes

setting variably a lens value of an illumination lens that leads multiple charged particle beams to a blanking aperture array mechanism, where a plurality of openings are formed, which individually performs blanking control for each beam of the multiple charged particle beams passing through the plurality of openings,

measuring a maximum movement amount for each the lens value from a reference positional relationship, while relatively moving a positional relationship between the multiple charged particle beams and the plurality of openings from the reference positional relationship in a range where a total current amount of beams passing through the plurality of openings for each the positional relationship is not less than a threshold, and

determining, using the maximum movement amount measured for each the lens value, the lens value of the illumination lens and outputting the lens value determined.

According to another aspect of the present invention, a multiple charged particle beam writing apparatus includes

an emission source configured to emit a charged particle beam,

an illumination lens configured to refract the charged particle beam,

a shaping aperture array substrate in which a plurality of first openings are formed, configured to form multiple charged particle beams by being irradiated with the charged particle beam refracted by the illumination lens and letting portions of the charged particle beam individually pass through the plurality of first openings,

a blanking aperture array mechanism in which a plurality of second openings are formed, configured to individually perform blanking control for each beam of the multiple charged particle beams passing through the plurality of second openings,

a moving mechanism configured to relatively move the shaping aperture array substrate and the blanking aperture array mechanism,

a current amount measurement mechanism configured to measure a total current amount of beams passing through the plurality of second openings,

a stage configured to mount thereon a target object on which a pattern is written by irradiation with the beams passing through the plurality of second openings,

a setting circuit configured to variably set a lens value of the illumination lens,

a movement amount measurement circuit configured to measure a maximum movement amount for each the lens value from a reference positional relationship, while relatively moving a positional relationship between the shaping aperture array substrate and the blanking aperture array mechanism from the reference positional relationship in a range where the total current amount of the beams passing through the plurality of second openings for each the positional relationship is not less than a threshold, and

a determination circuit configured to determine, using the maximum movement amount measured for each the lens value, the lens value of the illumination lens.

According to yet another aspect of the present invention, a non-transitory computer-readable storage medium storing a program for causing a computer to execute processing includes

setting variably a lens value of an illumination lens which leads multiple charged particle beams to a blanking aperture array mechanism, where a plurality of openings are formed, which individually performs blanking control for each beam of the multiple charged particle beams passing through the plurality of openings,

measuring a maximum movement amount for each the lens value from a reference positional relationship, while relatively moving a positional relationship between the multiple charged particle beams and the plurality of openings from the reference positional relationship in a range where a total current amount of beams passing through the plurality of openings for each the positional relationship is not less than a threshold,

storing the maximum movement amount measured for each the lens value in a storage device, and

reading the maximum movement amount for each the lens value stored in the storage device, and determining the lens value of the illumination lens by using the maximum movement amount read for each the lens value, and outputting the lens value determined.

### BRIEF DESCRIPTION OF THE DRAWINGS

FIG. 1 is an illustration showing a schematic diagram of a configuration of a writing apparatus according to a first embodiment;

FIG. 2 is a conceptual diagram showing a configuration of a shaping aperture array substrate according to the first embodiment;

FIG. 3 is a sectional view showing a configuration of a blanking aperture array mechanism according to the first embodiment;

FIG. 4 is a conceptual diagram showing an example of a writing operation according to the first embodiment;

FIG. 5 is an illustration showing an example of an irradiation region of multiple beams and a writing target pixel according to the first embodiment;

FIG. 6 is an illustration for explaining an example of a multi-beam writing operation according to the first embodiment;

FIG. 7 is an illustration showing an example of a relationship among a lens value of an illumination system lens, a current density distribution, and a maximum value of a total current amount according to a comparative example of the first embodiment;

FIG. 8 is an illustration showing an example of a beam array shape on a surface of a target object according to a comparative example of the first embodiment;

FIG. 9 is an illustration showing an example of a beam trajectory according to a comparative example of the first embodiment;

FIG. 10 is a flowchart showing an example of main steps of a writing method according to the first embodiment;

FIG. 11 is an illustration showing an example of a positional relationship between a shaping aperture array substrate and a blanking aperture array mechanism according to the first embodiment;

FIG. 12 is an illustration showing an example of a relation between a total current amount and a shift position according to the first embodiment;

FIG. 13 is an illustration for explaining a method of measuring a margin according to the first embodiment;

FIG. 14 is an illustration for explaining a parameter value on a total current amount in the case of including the total current amount in a parameter according to the first embodiment;

FIG. 15 is an illustration for explaining a parameter value on a current density in the case of including the current density in a parameter according to the first embodiment;

FIG. 16 is an illustration for explaining a method of measuring a current density according to the first embodiment;

FIG. 17 is an illustration showing an example of a relationship among an illumination system lens value, a margin, and a current density according to the first embodiment;

FIG. 18 is an illustration showing an example of a beam array shape on a surface of a target object according to the first embodiment; and

FIG. 19 is an illustration showing an example of beam illumination by an illumination system lens according to the first embodiment.

### DETAILED DESCRIPTION OF THE INVENTION

Embodiments of the present invention provide a method which can at least one of improve a current density distribution, reduce local beam distortion, reduce local beam blur, and reduce local position deviation.

Embodiments of the present invention describe a configuration in which an electron beam is used as an example of a charged particle beam. The charged particle beam is not limited to the electron beam, and other charged particle beams such as an ion beam may also be used.

### First Embodiment

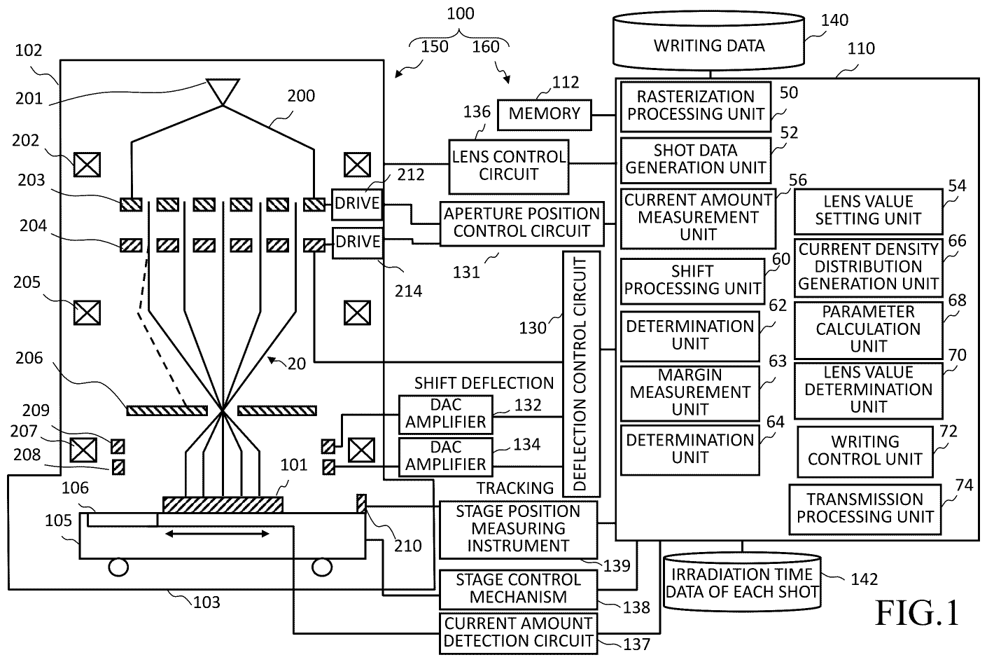

FIG. 1 is an illustration showing a schematic diagram of a configuration of a writing or “drawing” apparatus according to a first embodiment. As shown in FIG. 1, a writing apparatus 100 includes a writing mechanism 150 and a control system circuit 160. The writing apparatus 100 is an example of a multiple charged particle beam writing apparatus and an example of a multiple charged particle beam exposure apparatus. The writing mechanism 150 includes an electron optical column 102 (electron beam column) and a writing chamber 103. In the electron optical column 102, there are disposed an electron gun 201, an illumination lens 202, a shaping aperture array substrate 203, a blanking aperture array mechanism 204, a reducing lens 205, a limiting aperture substrate 206, an objective lens 207, a main deflector 208, a sub deflector 209, drive mechanism 212, and a drive mechanism 214.

In the writing chamber 103, an XY stage 105 is disposed. On the XY stage 105, there is placed a target object or “sample” 101, such as a mask, serving as a writing target substrate when writing (exposure) is performed. For example, the target object 101 is an exposure mask used in fabricating semiconductor devices, or a semiconductor substrate (silicon wafer) for fabricating semiconductor devices. The target object 101 may be a mask blank on which resist has been applied and nothing has yet been written. On the XY stage 105, a mirror 210 for measuring the position of the XY stage 105 is placed.

Furthermore, on the XY stage 105, a Faraday cup 106 is disposed. Although, in the example of FIG. 1, the Faraday cup 106 is arranged on the XY stage 105, it is not limited thereto. It is sufficient for the Faraday cup 106 to be located at the downstream side, in the beam advancing direction, of the blanking aperture array mechanism 204 and the position where the whole of the multiple beams can be detected.

The control system circuit 160 includes a control

computer 110, a memory 112, a deflection control circuit 130, an aperture position control circuit 131, digital-analog converter (DAC) amplifier units 132 and 134, a lens control circuit 136, a current amount detection circuit 137, a stage control mechanism 138, a stage position measuring instrument 139, and storage devices 140 and 142 such as magnetic disk drives. The control computer 110, the memory 112, the deflection control circuit 130, the aperture position control circuit 131, the lens control circuit 136, the current amount detection circuit 137, the stage control mechanism 138, the stage position measuring instrument 139, and the storage devices 140 and 142 are connected to each other through a bus (not shown). The DAC amplifier units 132 and 134 and the blanking aperture array mechanism 204 are connected to the deflection control circuit 130. The sub deflector 209 is composed of at least four electrodes (or “at least four poles”), and controlled by the deflection control circuit 130 through the DAC amplifier 132 disposed for each electrode. The main deflector 208 is composed of at least four electrodes (or “at least four poles”), and controlled by the deflection control circuit 130 through the DAC amplifier 134 disposed for each electrode. Electromagnetic lenses, such as the illumination lens 202, the reducing lens 205, and the objective lens 207, are controlled by the lens control circuit 136.

The position of the XY stage 105 is controlled by the drive of each axis motor (not shown) which is controlled by the stage control mechanism 138. Based on the principle of laser interferometry, the stage position measurement instrument 139 measures the position of the XY stage 105 by receiving a reflected light from the mirror 210.

The position of the shaping aperture array substrate 203 can be moved by the drive mechanism 212 which is controlled by the aperture position control circuit 131. The shaping aperture array substrate 203 moves in a direction in a plane perpendicular to the central axis of the multiple beams 20. Similarly, the position of the blanking aperture array mechanism 204 can be moved by the drive mechanism 214 which is controlled by the aperture position control circuit 131. The blanking aperture array mechanism 204 moves in the direction of a plane perpendicular (vertical) to the central axis of the multiple beams 20. By these mechanisms, the positional relationship between the shaping aperture array substrate 203 and the blanking aperture array mechanism 204 can be relatively changed by moving either one or both of them. In other words, the moving mechanism, such as the drive mechanisms 212 and 214, relatively moves the shaping aperture array substrate 203 and the blanking aperture array mechanism 204 in the direction perpendicular to the central axis of the trajectory of the multiple beams 20. The drive mechanism 212 may further move the shaping aperture array substrate 203 in the direction of the central axis of the multiple beams 20, (the z direction). Similarly, the drive mechanism 214 may further move the blanking aperture array mechanism 204 in the direction of the central axis of the multiple beams 20, (the z direction).

Data of the current amount detected by the Faraday cup 106 is output to the current amount detection circuit 137, and, after being converted into digital data by the current amount detection circuit 137, it is output to the control computer 110. For example, the Faraday cup 106 is simultaneously irradiated with all of the multiple beams 20, and measures the current amount of the entire multiple beams 20. Alternatively, the Faraday cup 106 is simultaneously irradiated with a portion of the multiple beams 20, and measures the current amount of the portion concerned of the multiple beams 20.

In the control computer 110, there are arranged a rasterization processing unit 50, a shot data generation unit 52, a lens value setting unit 54, a current amount measurement unit 56, a shift processing unit 60, a determination unit 62, a margin measurement unit 63, a determination unit 64, a current density distribution generation unit 66, a parameter calculation unit 68, a lens value determination unit 70, a writing control unit 72, and a transmission processing unit 74. Each of the “ . . . units” such as the rasterization processing unit 50, the shot data generation unit 52, the lens value setting unit 54, the current amount measurement unit 56, the shift processing unit 60, the determination unit 62, the margin measurement unit 63, the determination unit 64, the current density distribution generation unit 66, the parameter calculation unit 68, the lens value determination unit 70, the writing control unit 72, and the transmission processing unit 74 includes processing circuitry. The processing circuitry includes, for example, an electric circuit, a computer, a processor, a circuit board, a quantum circuit, a semiconductor device, or the like. Each “ . . . unit” may use common processing circuitry (the same processing circuitry), or different processing circuitry (separate processing circuitry). Information input/output to/from the rasterization processing unit 50, the shot data generation unit 52, the lens value setting unit 54, the current amount measurement unit 56, the shift processing unit 60, the determination unit 62, the margin measurement unit 63, the determination unit 64, the current density distribution generation unit 66, the parameter calculation unit 68, the lens value determination unit 70, the writing control unit 72, and the transmission processing unit 74, and information being operated are stored in the memory 112 each time.

Writing operations of the writing apparatus 100 are controlled by the writing control unit 72. In other words, the writing control unit 72 (an example of a control circuit) controls the writing mechanism 150. Processing of transmitting irradiation time data of each shot to the deflection control circuit 130 is controlled by the transmission control unit 74.

Writing data (chip data) is input from the outside of the writing apparatus 100, and stored in the storage device 140. Chip data defines information on a plurality of figure patterns configuring a chip pattern. Specifically, for example, coordinates for each vertex are defined for each figure pattern in the order of configuration of the figure. Alternatively, for example, a figure code, coordinates, a size, and the like are defined for each figure pattern.

FIG. 1 shows a configuration necessary for describing the first embodiment. Other configuration elements generally necessary for the writing apparatus 100 may also be included therein.

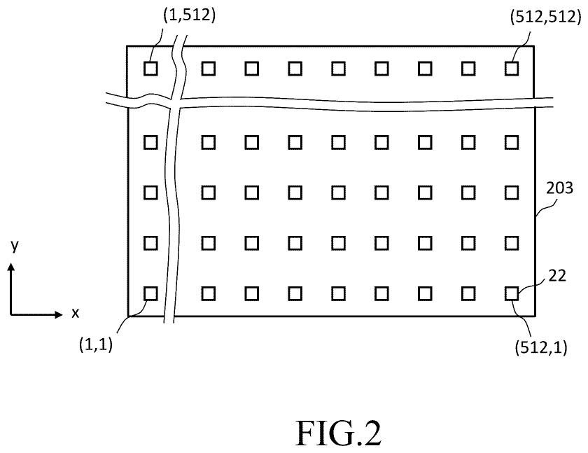

FIG. 2 is a conceptual diagram showing a configuration of a shaping aperture array substrate according to the first embodiment. As shown in FIG. 2, holes (openings) 22 of p rows long (length in the y direction) and q columns wide (width in the x direction) (p≥2, q≥2) are formed, like a matrix, at a predetermined arrangement pitch in the shaping aperture array substrate 203. In the case of FIG. 2, for example, holes 22 of 512×512, that is 512 holes in the y direction and 512 holes in the x direction, are formed. The number of the holes 22 is not limited thereto. For example, it is also preferable to form the holes 22 of 32×32. Each of the holes 22 is a rectangle (including square) having the same dimension and shape as each other. Alternatively, each of the holes 22 may be a circle with the same diameter as each other. The multiple beams 20 are formed by letting portions of an electron beam 200 individually pass through a corresponding one of a plurality of holes 22. In other words, the shaping aperture array substrate 203 forms the multiple beams 20.

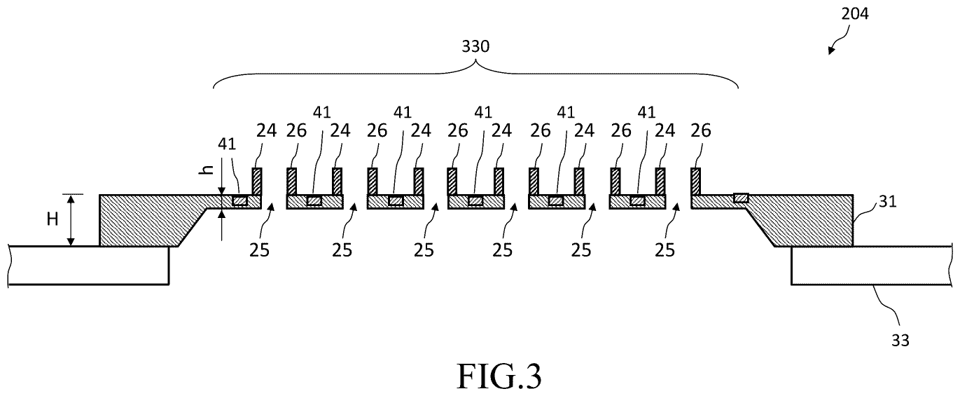

FIG. 3 is a sectional view showing a configuration of a blanking aperture array mechanism according to the first embodiment. In the blanking aperture array mechanism 204, as shown in FIG. 3, a blanking aperture array substrate 31 being a semiconductor substrate made of silicon, etc. is disposed on a support table 33. In a membrane region 330 at the center of the blanking aperture array substrate 31, a plurality of passage holes 25 (openings), through each of which a corresponding one of the multiple beams 20 passes, are formed at positions each corresponding to each hole 22 in the shaping aperture array substrate 203 shown in FIG. 2. A pair of a control electrode 24 and a counter electrode 26, (blanker: blanking deflector), is arranged in a manner such that the electrodes 24 and 26 are opposite to each other across a corresponding one of the plurality of the passage holes 25. A control circuit 41 (logic circuit) which applies a deflection voltage to the control electrode 24 for the passage hole 25 concerned is disposed, inside the blanking aperture array substrate 31, close to each corresponding passage hole 25. The counter electrode 26 for each beam is grounded.

In the control circuit 41, an amplifier (not

shown) (an example of a switching circuit) is arranged. As an example of the amplifier, a CMOS (Complementary MOS) inverter circuit serving as a switching circuit is disposed. With regard to inputs (IN) to the CMOS inverter circuit, either an L (low) potential (e.g., ground potential) lower than a threshold voltage, or an H (high) potential (e.g., 1.5 V) higher than or equal to the threshold voltage is applied as a control signal. According to the first embodiment, in a state where an L potential is applied to the input (IN) of the CMOS inverter circuit, the output (OUT) of the CMOS inverter circuit, which is to be applied to the control circuit 41, becomes a positive potential (Vdd), and then, a corresponding beam is deflected by an electric field due to a potential difference from the ground potential of the counter electrode 26, and is controlled to be in a beam OFF condition by being blocked by the limiting aperture substrate 206. In contrast, in a state (active state) where an H potential is applied to the input (IN) of the CMOS inverter circuit, the output (OUT) of the CMOS inverter circuit becomes a ground potential, and therefore, since there is no potential difference from the ground potential of the counter electrode 26, a corresponding beam is not deflected, and is controlled to be in a beam ON condition by passing through the limiting aperture substrate 206. Blanking control is provided by such deflection.

Next, operations of the writing mechanism 150 will be described. The electron beam 200 emitted from the electron gun 201 (emission source) is refracted by the illumination lens 202, and applied, ideally almost perpendicularly (e.g., vertically), to the whole of the shaping aperture array substrate 203. A plurality of rectangular holes 22 (openings) are formed in the shaping aperture array substrate 203. The region including all of the plurality of holes 22 is irradiated with the electron beam 200. For example, rectangular multiple beams (a plurality of electron beams) 20 are formed by letting portions of the electron beam 200 applied to the positions of the plurality of holes 22 individually pass through a corresponding one of the plurality of holes 22 in the shaping aperture array substrate 203. The multiple beams 20 individually pass through corresponding blankers of the blanking aperture array mechanism 204. The blanker provides blanking control such that a corresponding beam individually passing becomes in an ON condition during a set writing time (irradiation time). In other words, the blanking aperture array mechanism 204 individually performs blanking control of each beam of the multiple beams 20 passing through a plurality of passage holes 25.

The multiple beams 20 having passed through the blanking aperture array mechanism 204 are reduced by the reducing lens 205, and travel toward the hole in the center of the limiting aperture substrate 206. Then, the electron beam which was deflected by the blanker of the blanking aperture array mechanism 204 deviates from the hole in the center of the limiting aperture substrate 206 and is blocked by the limiting aperture substrate 206. In contrast, the electron beam which was not deflected by the blanker of the blanking aperture array mechanism 204 passes through the hole in the center of the limiting aperture substrate 206 as shown in FIG. 1. Thus, the limiting aperture substrate 206 blocks each beam which was deflected to be in the OFF state by the blanker of the blanking aperture array mechanism 204. Then, each beam for one shot of the multiple beams 20 is formed by a beam which has been made during a period from becoming beam ON to becoming beam OFF and has passed through the limiting aperture substrate 206. The multiple beams 20 having passed through the limiting aperture substrate 206 are focused by the objective lens 207 so as to be a pattern image of a desired reduction ratio. Then, all of the multiple beams 20 having passed through the limiting aperture substrate 206 are collectively deflected in the same direction by the main deflector 208 and the sub deflector 209 in order to irradiate respective beam irradiation positions on the target object 101. For example, when the XY stage 105 is continuously moving, tracking control is performed by the main deflector 208 so that the beam irradiation position may follow the movement of the XY stage 105. Ideally, the multiple beams 20 irradiating at a time are aligned at a pitch obtained by multiplying the arrangement pitch of a plurality of holes 22 in the shaping aperture array substrate 203 by the desired reduction ratio described above.

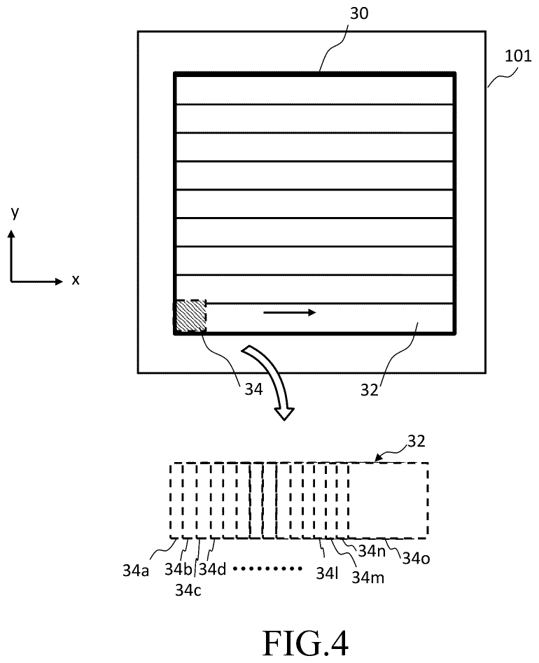

FIG. 4 is a conceptual diagram showing an example of a writing operation according to the first embodiment. As shown in FIG. 4, a writing region 30 (bold line) of the target object 101 is virtually divided into a plurality of stripe regions 32 by a predetermined width in the y direction, for example. In the case of FIG. 4, the writing region 30 of the target object 101 is divided in the y direction, for example, into a plurality of stripe regions 32 by the width size being substantially the same as the design size of an irradiation region 34 (writing field) that can be irradiated with one irradiation of the multiple beams 20.

Although FIG. 4 shows the case where each stripe region 32 is individually written once, it is not limited thereto. Each stripe region 32 may be individually written a plurality of times. Furthermore, it is also acceptable to perform multiple writing of multiplicity N, that is N-pass multiple writing, (N being an integer of 2 or more), meaning to write the same stripe region 32 N times by moving the stage N times, that is N passes, in the x direction or −x direction. In the case of performing N-pass multiple writing, it is preferable to write the stripe region 32 to be partially overlapped while shifting, in each pass, the position of the stripe region 32 in the y direction. As a shifting amount for one pass, preferably, 1/N of the width of the stripe region 32 is shifted, for example.

The direction of the position shifting is not limited to the y direction. It is also preferable to shift in the x direction. Next, an example of the writing operation will be explained below.

First, the XY stage 105 is moved to make an adjustment such that the irradiation region 34 of the multiple beams 20 is located at the left end, or at a position further left than the left end, of the first stripe region 32. Then, when performing writing to the first stripe region 32, the XY stage 105 is moved, for example, in the −x direction, so that the writing may relatively proceed in the x direction. The XY stage 105 is moved, for example, continuously at a constant speed.

After performing writing to the first stripe region 32, the stage position is moved in the-y direction by the width size of the stripe region 32. Thereby, the stripe region 32 to be written is shifted in the y direction by the width size of the stripe region 32.

Next, an adjustment is made so that the irradiation region 34 of the multiple beams 20 can be located at the left end, or at a position further left than the left end, of the second stripe region 32. By moving the XY stage 105, for example, in the −x direction, the writing relatively proceeds in the x direction. Thereby, writing is performed to the second stripe region 32. Hereafter, by repeating similar operations, writing to all the stripe regions 32 is performed.

FIG. 4 shows the case where each stripe region 32 is written in the same direction, but, it is not limited thereto. For example, with respect to the stripe region 32 to be written following the stripe region 32 having already been written in the x direction, it may be written in the −x direction by moving the XY stage 105 in the x direction, for example. Thus, due to performing writing while alternately changing the writing direction, the stage moving time can be reduced, which results in reducing the writing time. Owing to one shot of multiple beams having been formed by individually passing through the holes 22 in the shaping aperture array substrate 203, a plurality of shot patterns maximally up to as many as the number of the holes 22 are formed at a time.

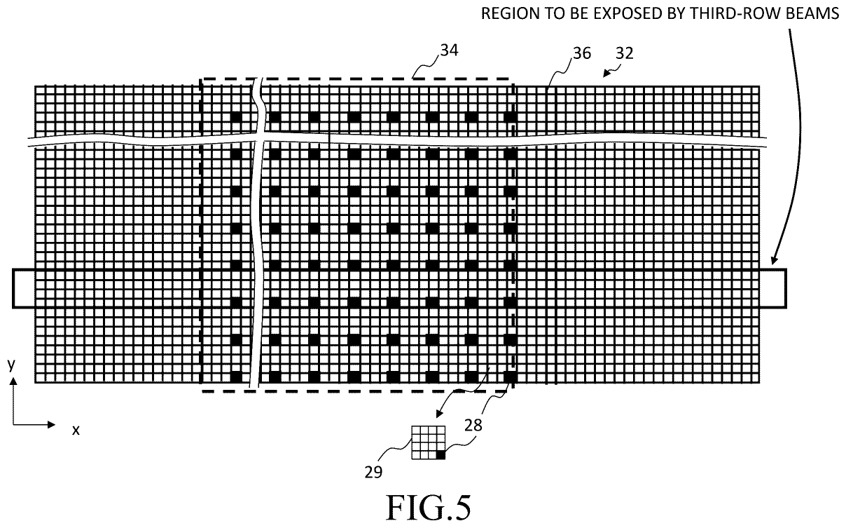

FIG. 5 is an illustration showing an example of an irradiation region of multiple beams and a pixel to be written (writing target pixel) according to the first embodiment. In FIG. 5, the stripe region 32 is divided into a plurality of mesh regions by the beam size of the multiple beams 20, for example. Each mesh region serves as a writing target pixel 36 (beam irradiation unit region, irradiation position). The size of the writing target pixel 36 is not limited to the beam size, and may be any size regardless of beam size. For example, it may be 1/n (n being an integer of 1 or more) of the beam size. FIG. 5 shows the case where the writing region of the target object 101 is divided, for example, in the y direction, into a plurality of stripe regions 32 by the width size being substantially the same as the size of the irradiation region 34 (writing field) that can be irradiated with one irradiation of the multiple beams 20. The x-direction size of the rectangular, including square, irradiation region 34 can be defined by (the number of x-direction beams)×(beam pitch in the x direction). The y-direction size of the rectangular irradiation region 34 can be defined by (the number of y-direction beams)×(beam pitch in the y direction). FIG. 5 shows the case of multiple beams of 512×512 (rows ×columns) having been simplified to 8×8 (rows×columns). In the irradiation region 34, there are shown a plurality of pixels 28 (beam writing positions) that can be irradiated with one shot of the multiple beams 20. The pitch between adjacent pixels 28 is the beam pitch of the multiple beams. A sub-irradiation region 29 (pitch cell region) is configured by a rectangular, including square, region surrounded by the size of beam pitches in the x and y directions. In the example of FIG. 5, each sub-irradiation region 29 is composed of 4×4 pixels, for example.

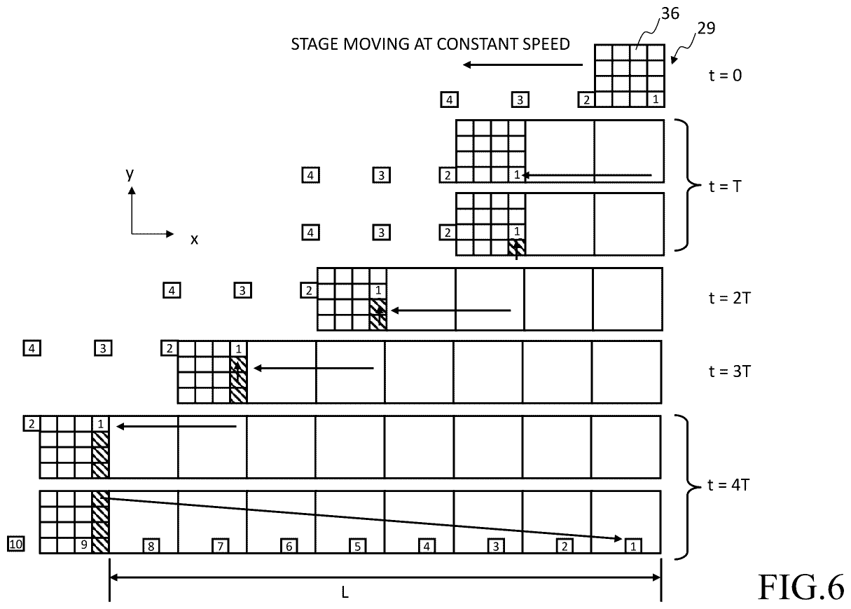

FIG. 6 is an illustration for explaining an example of a multi-beam writing operation according to the first embodiment. FIG. 6 shows the case where the inside of each sub-irradiation region 29 is written with four different beams. Furthermore, the example of FIG. 6 shows a writing operation where the XY stage 105 continuously moves at the speed at which the XY stage 105 moves the distance L of eight beam pitches while a ¼ region, namely the region of 1/(the number of beams used for irradiation), in each sub-irradiation region 29 is written. In the writing operation shown in FIG. 6, for example, while the XY stage 105 moves the distance L of eight beam pitches, different four pixels in the same sub-irradiation region 29 are written (exposed) by being applied with four shots of the multiple beams 20 at a shot cycle T with shifting the irradiation position (pixel 36) in order by the sub deflector 209. In order that the relative position between the irradiation region 34 and the target object 101 may not be shifted by the movement of the XY stage 105 while these four pixels 36 are written (exposed), the irradiation region 34 is made to follow the movement of the XY stage 105 by collective deflection of all of the multiple beams 20 by the main deflector 208. In other words, a tracking control is performed. After one tracking cycle is completed, tracking is reset to return to the previous (last) tracking starting position. Since writing of the pixels in the first column from the right of each sub-irradiation region 29 has been completed, in the next tracking cycle after resetting the tracking, first, the sub deflector 209 provides deflection such that the beam writing position is adjusted (shifted) to write the second pixel column from the right still not having been written in each sub-irradiation region 29, for example. By repeating this operation during writing the stripe region 32, as shown in the lower part of FIG. 4, the position of the irradiation region 34 of the multiple beams 20 is sequentially moved (shifted), such as the irradiation region 34a, 34b, 34c, . . . ,34o, to perform writing.

As described above, the multiple beams 20 are formed by irradiating the shaping aperture array substrate 203 with the electron beam 200 by the illumination lens 202. Then, the formed multiple beams 20 are led to the blanking aperture array mechanism 204 by the illumination lens 202. The current amount of the multiple beams 20 is affected by the illumination lens 202 which leads the multiple beams to the blanking aperture array mechanism 204.

Conventionally, a value at which the total current amount of the multiple beams having passed through the blanking control mechanism is maximum is set as a lens value of the illumination system lens, where the lens value means an input value to the target lens, or means, in the case of the lens concerned being an electromagnetic lens, a value of the current to flow through the coil of the electromagnetic lens, and, in the case of the lens concerned being an electrostatic lens, a voltage value to be applied to the electrode of the electrostatic lens. However, it has turned out that, according to this method, the current density distribution may not be optimized.

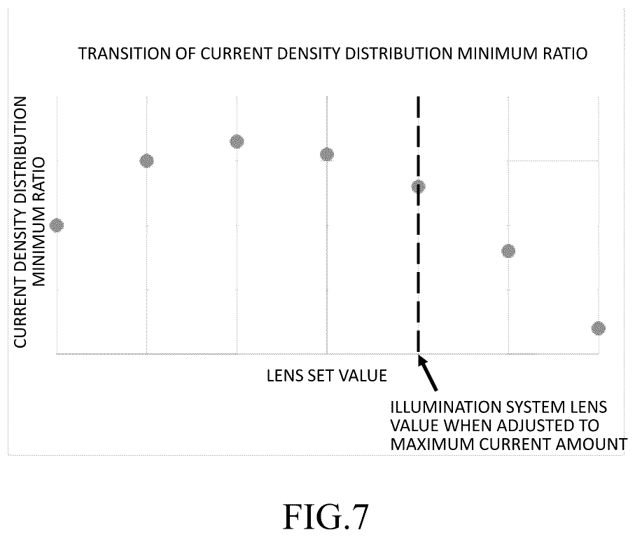

FIG. 7 is an illustration showing an example of a relationship among a lens value of an illumination system lens, a current density distribution, and a maximum value of a total current amount according to a comparative example of the first embodiment. In FIG. 7, the ordinate axis represents a current distribution minimum value ratio which shows a ratio of the minimum value to the maximum value in a current density distribution, and the abscissa axis represents a relative value of a lens value. The example of FIG. 7 shows a relative lens value referring to, as a reference, a lens value at which the total current amount of the multiple beams 20 is maximum. As shown in FIG. 7, it turns out there is a lens value whose current distribution minimum ratio is larger than that of the case of setting a lens value, at which the total current amount of the multiple beams 20 is maximum, on the illumination system lens.

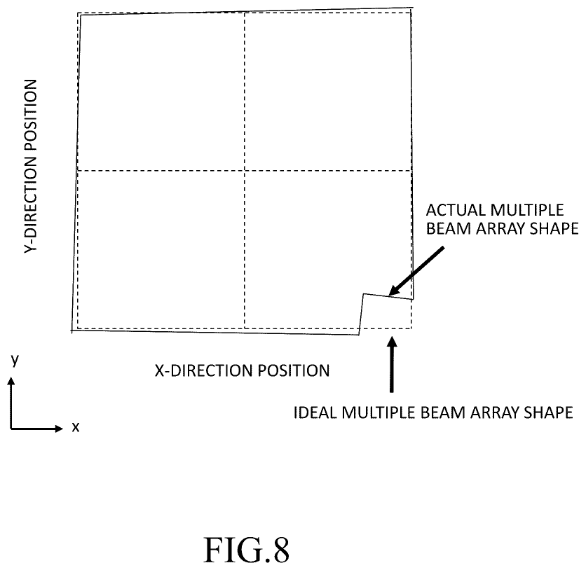

FIG. 8 is an illustration showing an example of a beam array shape on the surface of a target object according to a comparative example of the first embodiment. As shown in the example of FIG. 8, in the beam array, the position of a beam is locally and largely deviated inward at one of the four corners, and therefore, a local beam distortion occurs in the beam array.

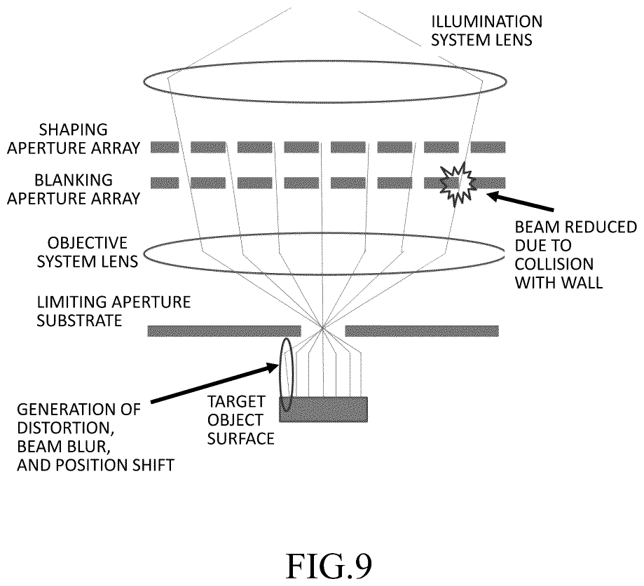

FIG. 9 is an illustration showing an example of a beam trajectory according to a comparative example of the first embodiment. FIG. 9 shows the case where some of formed multiple beams pass while colliding with the wall surface of the opening of the blanking aperture array mechanism by electron beams refracted by the illumination system lens. Thereby, the shape of formed beams is locally reduced. Therefore, a local positional deviation is detected on the surface of the target object, and since the distance to the target object surface changes due to the positional deviation, the focus position is displaced, and thus, a beam blur occurs.

As described above, with regard to the conventional method, it turns out that local distortion of a beam array shape, a beam blur, and/or a positional deviation may be generated in addition to the current density distribution not being optimized. Then, according to the first embodiment, the lens value is not determined based on a total current amount, but the lens value is determined by mainly using another method. It will be specifically described.

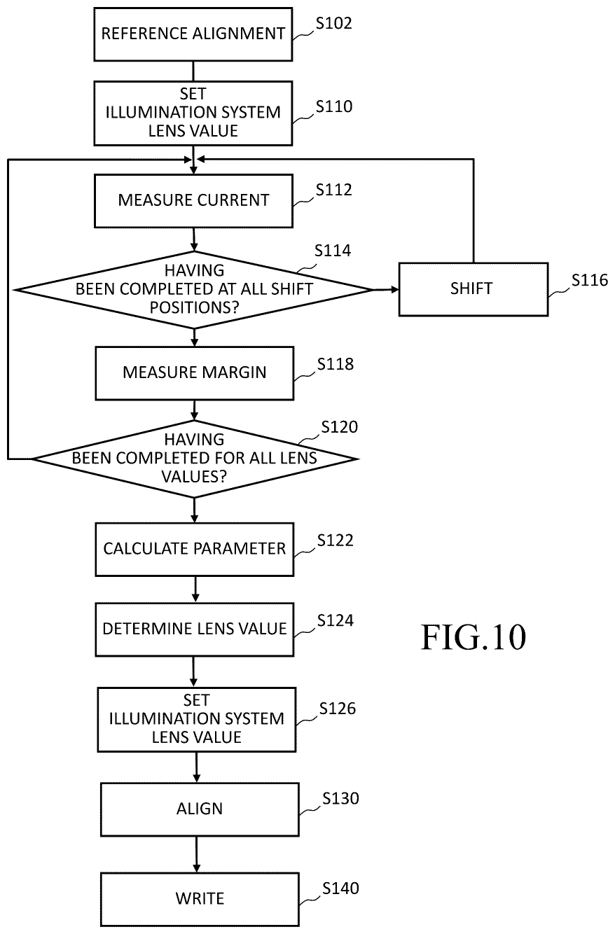

FIG. 10 is a flowchart showing an example of main steps of a writing method according to the first embodiment. In FIG. 10, the writing method of the first embodiment executes a series of steps: a reference alignment step (S102), an illumination system lens value setting step (S110), a current measurement step (S112), a determination step (S114), a shift step (S116), a margin measurement step (S118), a determination step (S120), a parameter calculation step (S122), a lens value determination step (S124), an illumination system lens value setting step (S126), an alignment step (S130), and a writing step (S140).

In the reference alignment step (S102), under the control of the aperture position control circuit 131, the drive mechanism 212 drives the shaping aperture array substrate 203 to be arranged at a design position. Similarly, under the control of the aperture position control circuit 131, the drive mechanism 214 drives the blanking aperture array mechanism 204 to be arranged at a design position. Thereby, a reference positional relationship (reference position) between the shaping aperture array substrate 203 and the blanking aperture array mechanism 204 is determined. Using an alignment coil (not shown) arranged at the electron gun 201 side with respect to the shaping aperture array substrate 203, the beam trajectory is adjusted such that, ideally, the central axis of the beam trajectory intersects perpendicularly to the shaping aperture array substrate 203 and the blanking aperture array mechanism 204.

In the illumination system lens value setting step (S110), the lens value setting unit 54 variably sets the lens value of the illumination lens 202 which leads the multiple beams 20 to the blanking aperture array mechanism 204 individually performing blanking control for each of the multiple beams 20 passing through a plurality of passage holes 25. Here, one of a plurality of lens values prepared beforehand is set. For example, it is preferable to prepare a plurality of lenses centering on a design lens value. Specifically, it operates as follows. The lens value setting unit 54 sets the lens value of the illumination lens 202 in the lens control circuit 136. The lens control circuit 136 controls the illumination lens 202 to be in accordance with the set lens value. Specifically, a current corresponding to the lens value is made to flow through a coil of an electromagnetic lens.

In the current measurement step (S112), the current amount measurement unit 56 measures, for each lens value and each positional relationship, a total current amount of beams which pass through a plurality of passage holes 25 of the blanking aperture array mechanism 204. Specifically, it operates as follows. Based on the present relative positional relationship between the present shaping aperture array substrate 203 and the blanking aperture array mechanism 204, the current amount measurement unit 56 measures the current amount of the multiple beams 20 having passed through the blanking aperture array mechanism 204. Specifically, it operates as follows. First, the XY stage 105 is moved to the position on which the multiple beams 20 can be received by the Faraday cup 106. The Faraday cup 106 receives irradiation of the multiple beams 20 having passed through the blanking aperture array mechanism 204. The Faraday cup 106 (an example of a current amount measurement mechanism) measures a total current amount of beams which pass through a plurality of passage holes 25 of the blanking aperture array mechanism 204. Detection data corresponding to the current amount of the multiple beams 20 detected by the Faraday cup 106 is converted in the current amount detection circuit 137 into a current amount of digital data, and output to the control computer 110. The current amount measurement unit 56 measures the amount of current of the multiple beams 20 by inputting a current amount detected by The Faraday cup 106 through the current amount detection circuit 137. If the Faraday cup 106 can measure the current amount of all the multiple beams 20 at a time, the measured value is measured as a total current amount of the multiple beams 20. If the Faraday cup 106 measures respective current amounts each for each partial beams of the multiple beams 20, the total value of measured respective values each for each partial beams is measured as a total current amount of the multiple beams 20.

In the determination step (S114), the determination unit 62 determines whether current measurement has been completed at all of shift positions. If current measurement has been completed at all of shift positions, it proceeds to the margin measurement step (S118), and if not, it proceeds to the shift step (S116).

In the shift step (S116), the shift processing unit 60 controls one or both of a drive unit 212 and a drive unit 214 through the aperture position control circuit 131 in order to shift the position of one or both of the shaping aperture array substrate 203 and the blanking aperture array mechanism 204. Thereby, one or both of the shaping aperture array substrate 203 and the blanking aperture array mechanism 204 is shifted in the direction orthogonal to the design central axis of the trajectory of the multiple beams 20. Therefore, ideally, one or both of the shaping aperture array substrate 203 and the blanking aperture array mechanism 204 is shifted in the direction orthogonal to the central axis of the trajectory of the multiple beams 20.

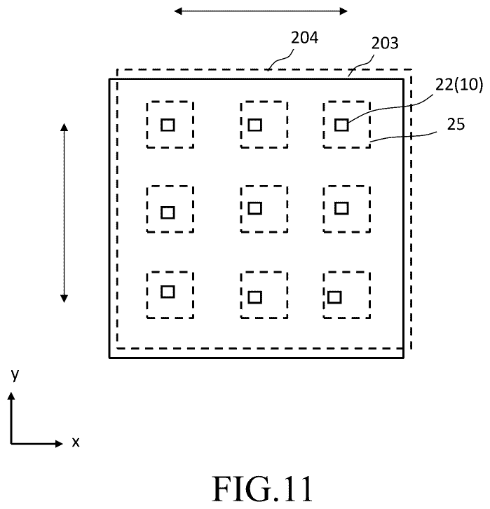

FIG. 11 is an illustration showing an example of a positional relationship between a shaping aperture array substrate and a blanking aperture array mechanism according to the first embodiment. Each beam 10 of the multiple beams 20 is formed to be the size of the hole 22 of the shaping aperture array substrate 203. The size of the passage hole 25 of the blanking aperture array mechanism 204 is larger than the size of each beam 10. Therefore, it is sufficient for the total shift amount to be the size of the passage hole 25 of the blanking aperture array mechanism 204. If the total shift amount is larger than the size of the passage hole 25, each beam 10 becomes out of the passage hole 25 of the blanking aperture array mechanism 204.

Then, the size of the passage hole 25 is divided into a plurality of shift amounts in order to set a plurality of shift positions whose mutual interval is the shift amount. In other words, the shift processing unit 60 moves, by the shift amount, the relative position between the shaping aperture array substrate 203 and the blanking aperture array mechanism 204. Here, the blanking aperture array mechanism 204, for example, is moved in the leftward (−x direction), for example, from the reference position by one shift amount. Then, it returns to the current measurement step (S112), and each step from the current measurement step (S112) to the shift step (S116) is performed until current measurement has been completed at all of shift positions.

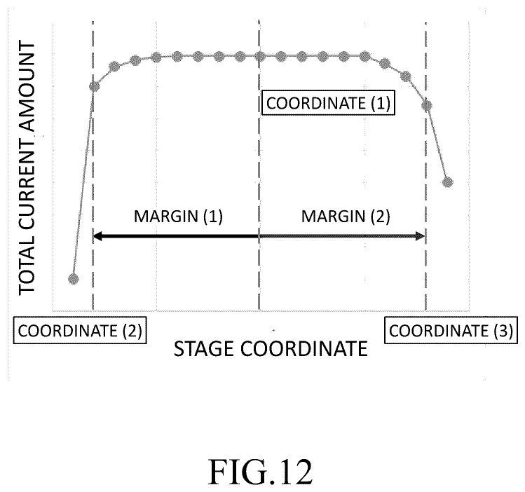

FIG. 12 is an illustration showing an example of a relation between a total current amount and a shift position according to the first embodiment. In FIG. 12, the ordinate axis represents a total current amount of the multiple beams 20. The abscissa axis represents a shift amount from the reference position (coordinates 1) of the shaping aperture array substrate 203 and the blanking aperture array mechanism 204. For example, in the state where the position of the shaping aperture array substrate 203 is fixed, the position of the blanking aperture array mechanism 204 is shifted by a shift amount each time. The blanking aperture array mechanism 204 is shifted forwards or backwards in the x direction from the reference position. Similarly, it is shifted forwards or backwards in the y direction from the reference position. Then, a total current amount is measured at each shift position. FIG. 12 depicts relative to the x direction, for example.

In the margin measurement step (S118), while relatively moving the positional relationship between the multiple beams 20 and a plurality of passage holes 25 from the reference positional relationship, the margin measurement unit 63 (movement amount measurement unit) measures a margin (maximum movement amount) for each lens value, in the direction orthogonal to the central axis of the trajectory of the multiple beams 20, from the reference positional relationship in the range where a total current amount of the multiple beams 20 (beams) passing through a plurality of passage holes 25 for each positional relationship is not less than a threshold Mth. It is preferable that the threshold Mth is set in the range of 99.0 to 99.9% of the total current amount at the reference position (coordinates 1), for example. More preferably, it is set in the range of 99.5 to 99.8% of the total current amount at the reference position (coordinates 1). For example, the threshold Mth is set to be 99.7% of the total current amount at the reference position (coordinates 1). Such a value of the threshold Mth is a ratio equivalent to the total current amount in the case where some outer peripheral beams of the multiple beams 20 do not reach the surface of the target object. The margin in the x direction is measured as a total value of a margin (1) in the −x direction from the reference position (coordinates 1) and a margin (2) in the +x direction from the reference position (coordinates 1). Similarly, the margin in the y direction is measured as a total value of a margin (1) in the −y direction from the reference position (coordinates 1) and a margin (2) in the +y direction from the reference position (coordinates 1). The measured margin for each lens value is stored in the storage device 142.

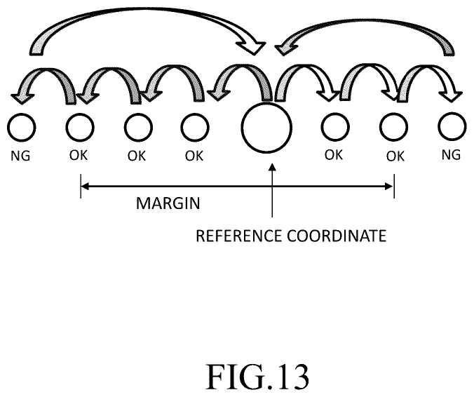

FIG. 13 is an illustration for explaining a method of measuring a margin according to the first embodiment. In FIG. 13, it is checked, in the −x direction from the reference position (coordinates 1), whether the total current amount at each shift position is equal to or greater than the threshold Mth. Then, a movement amount from the reference position to the shift position being adjacently previous to the shift position at which the total current amount becomes less than the threshold Mth is defined as a margin (1). Similarly, it is checked, in the +x direction from the reference position (coordinates 1), whether the total current amount at each shift position is equal to or greater than the threshold Mth. Then, a movement amount from the reference position to the shift position being adjacently previous to the shift position at which the total current amount becomes less than the threshold Mth is defined as a margin (2). The same applies to the case in the y direction.

As described above, the margin (the maximum movement amount) at the lens value concerned can be measured.

In the determination step (S120), the determination unit 64 determines whether current measurement has been completed for all of preset lens values. If current measurement has been completed for all of the lens values, it proceeds to the parameter calculation step (S122). If current measurement has not been completed for all of shift positions, it returns to the current measurement step (S112), the set value of the illumination lens 202 is changed to a lens value for which current measurement has not yet been carried out in a plurality of preset lens values, and each step from the current measurement step (S112) to the determination step (S120) is repeated until current measurement has been completed for all of the lens values.

In the parameter calculation step (S122), the parameter calculation unit 68 calculates the value of the parameter function “f” which uses, as a parameter, only a margin “a” for each lens value. The parameter function “f” is defined by the following equation (1-1). The coefficient “P” is defined by the reciprocal of the design margin “A” and the equation (1-2). “i” indicates an index of a lens value.

$$f ( i ) = P \cdot a ( i ) \qquad ( 1 - 1 )$$

$$P = 1 / R \qquad ( 1 - 2 )$$

As described above, there are a margin in the x direction and a margin in the y direction. As a margin a (i), a statistic value of both the margins, such as an average value, a maximum value, or a minimum value may be used. Alternatively, as the margin a (i), a total value of both the margins may be used. Alternatively, a preset one of them may be used as the margin a (i). For example, the margin in the x direction is used.

Alternatively, the parameter calculation unit 68 calculates the value of the parameter function “f” which uses, as parameters, a margin a (i) for each lens value and a total current amount b (i) for each lens value. The parameter function “f” is defined by the following equation (2-1). The coefficient “P” is preferably defined by the reciprocal of a design margin. “i” indicates an index of a lens value. The function Q (b) is defined by the following equations (2-2) and (2-3) using the design value B of the total current amount. The total current amount b (i) for each lens value uses a total current amount measured at the reference position for each lens value. Alternatively, the maximum value in a plurality of total current amounts measured at the same lens value may be used.

$$f ( i ) = P \cdot a ( i ) + ( Q ( b ( i ) ) \qquad ( 2 - 1 )$$

$$( Q ( b ( i ) ) = ( 2 B - b ( i ) ) / B ( b ( i ) \geq B ) \qquad ( 2 - 2 )$$

$$( Q ( b ( i ) ) = b ( i ) / B ( b ( i ) < B ) \qquad ( 2 - 3 )$$

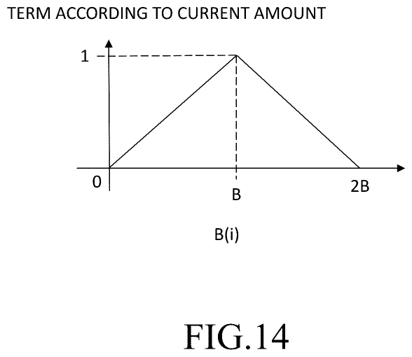

FIG. 14 is an illustration for explaining a parameter value on a total current amount in the case of including the total current amount in a parameter according to the first embodiment. When each lens total current amount b (i)<B, the larger the total current amount b (i) is, the higher the function Q (b) goes up toward 1. When the total current amount b (i)=B, the function Q (b) is 1. When the total current amount b (i)>B, the larger the total current amount b (i) is, the lower the function Q (b) goes down toward 0.

Alternatively, the parameter calculation unit 68

calculates the value of the parameter function “f” which uses, as parameters, a margin a (i) for each lens value, and a current density distribution minimum ratio c (i) for each lens value that is a ratio (%) of the minimum value to the maximum value acquired from the measured current density distribution. The parameter function “f” is defined by the following equation (3-1). The coefficient “P” is preferably defined by the reciprocal (1/A) of the design margin “A”. “i” indicates an index of a lens value. The function R (c) is defined by the following equation (3-2). As the current density distribution for each lens value, a current density distribution measured at the reference position is used. Alternatively, it is also preferable to use a current density distribution in which the difference between the maximum value and the minimum value is smallest, in a plurality of current density distributions measured at the same lens value.

$$f ( i ) = P \cdot a ( i ) + R ( c ( i ) ) \qquad ( 3 - 1 )$$

$$R ( c ) = c ( i ) \cdot 100 \qquad ( 3 - 2 )$$

The ratio of the minimum value to the maximum value acquired from the current density distribution, which shows a current density distribution minimum ratio c (i), may be defined by a ratio (=minimum/maximum) instead of a percentage. In that case, needless to say, R (c)=c (i).

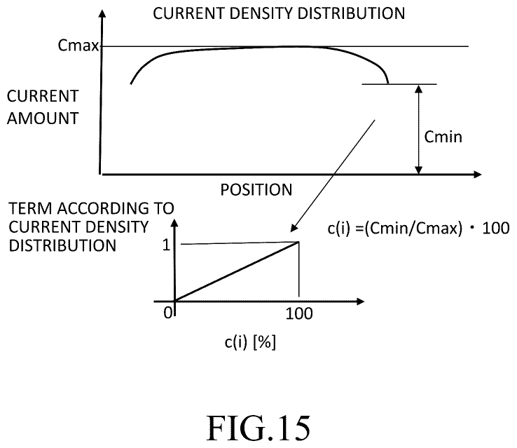

FIG. 15 is an illustration for explaining a parameter value on a current density in the case of including the current density in a parameter according to the first embodiment. The larger the current density distribution minimum ratio c (i) for each lens value is, the higher the function R (c) goes up toward 1.

In the case of including a current density in the parameter function “f”, a current density distribution of beams which pass through a plurality of passage holes 25 of the blanking aperture array mechanism 204 is measured for each lens value. Specifically, it operates as follows.

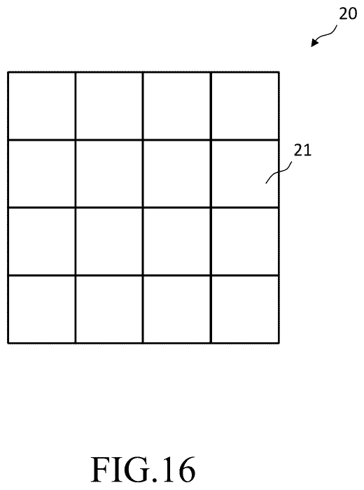

FIG. 16 is an illustration for explaining a method of measuring a current density according to the first embodiment. In FIG. 16, a beam array which configures the multiple beams 20 is divided into a plurality of blocks 21 in a grid form. Each block 21 includes m×m beams (m being an integer of 2 or more). In the current measurement step (S112) performed, for each lens value, in the relative positional relationship between the shaping aperture array substrate 203 and the blanking aperture array mechanism 204 being the reference position, the current amount measurement unit 56 further measures a current amount for each block. In the state where beams for other than a target block are “beam OFF”, the Faraday cup 106 receives beams for the target block, and measures the amount of current. Detection data corresponding to the current amount of the multiple beams 20 detected by the Faraday cup 106 is converted in the current amount detection circuit 137 into a current amount of digital data, and output to the control computer 110.

Then, the current density distribution generation unit 66 inputs a current amount for each block measured by the Faraday cup 106 through the current amount detection circuit 137 in order to generate a current density distribution of the multiple beams 20.

As described above, the current density distribution for each lens value is measured.

Alternatively, the parameter calculation unit 68 calculates the value of the parameter function “f” which uses, as parameters, a margin a (i) for each lens value, a total current amount b (i) for each lens value, and a current density distribution minimum ratio c (i) for each lens value. The parameter function “f” is defined by the following equation (4). The value of each term in the right side is what is described above.

$$f ( i ) = P \cdot a ( i ) + ( Q ( b ( i ) ) + R ( c ( i ) ) \qquad ( 4 )$$

In the lens value determination step (S124), the lens value determination unit 70 determines, using a measured margin for each lens value, the lens value of the illumination lens 202 and outputs it. Specifically, it operates as follows. The lens value determination unit 70 determines the lens value of the illumination lens 202 by the function “f” of the equation (1-1) using, as a parameter, only a margin a (i) for each lens value. Alternatively, the lens value determination unit 70 determines the lens value of the illumination lens 202 by the function “f” of the equation (2-1) using, as parameters, a margin a (i) for each lens value, and a total current amount b (i) for each lens value. Alternatively, the lens value determination unit 70 determines the lens value of the illumination lens 202 by the function “f” of the equation (3-1) using, as parameters, a margin a (i) for each lens value, and a current density distribution minimum ratio c (i) for each lens value. Alternatively, the lens value determination unit 70 determines the lens value of the illumination lens 202 by the function “f” of the equation (4) using, as parameters, a margin a (i) for each lens value, a total current amount b (i) for each lens value, and a current density distribution minimum ratio c (i) for each lens value.

Specifically, the lens value according to the function “f” whose value is the largest is determined as the lens value of the illumination lens 202 by the lens value determination unit 70. In the case of determining the lens value of the illumination lens 202 by using only a margin a (i) for each lens value, the lens value at which the margin is largest may be determined as the lens value of the illumination lens 202 without calculating the function “f”. The determined lens value is output to the lens control circuit 136.

In the illumination system lens value setting step (S126), the lens control circuit 136 sets the input lens value as the lens value of the illumination lens 202. The lens control circuit 136 controls the illumination lens 202 to be matched with the set lens value. Specifically, a current corresponding to the lens value is made to flow through the coil of an electromagnetic lens.

In the alignment step (S130), under the control of the aperture position control circuit 131, the drive mechanism 212 drives the shaping aperture array substrate 203 to be arranged at a design position. Similarly, under the control of the aperture position control circuit 131, the drive mechanism 214 drives the blanking aperture array mechanism 204 to be arranged at a design position. In other words, alignment is performed such that the shaping aperture array substrate 203 and the blanking aperture array mechanism 204 are returned to the reference position. Alternatively, alignment between the shaping aperture array substrate 203 and the blanking aperture array mechanism 204 may be performed to have a positional relationship of the shift position where the total current amount is maximum at the set lens value.

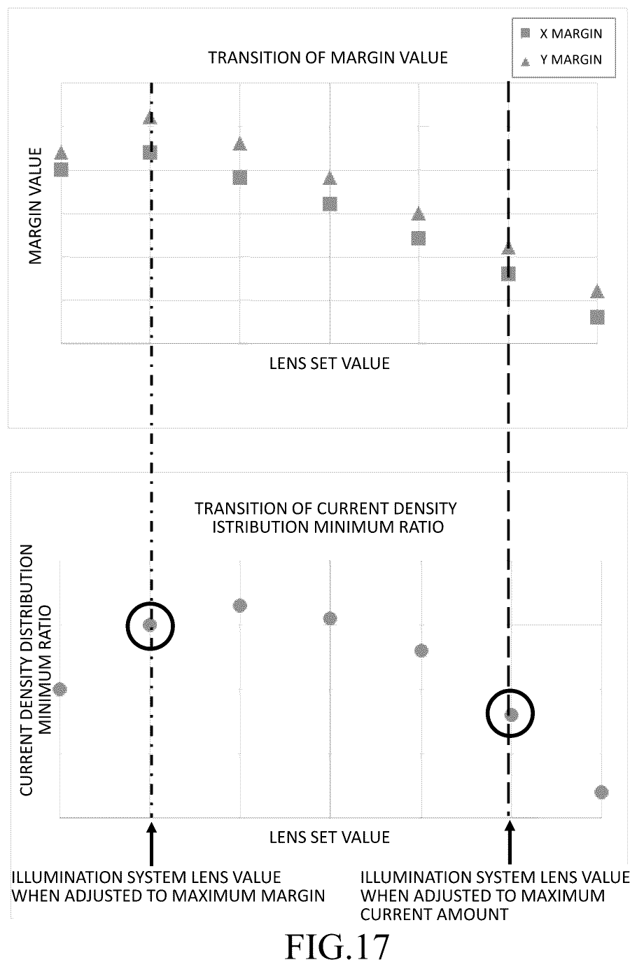

FIG. 17 is an illustration showing an example of a relationship among an illumination system lens value, a margin, and a current density according to the first embodiment. In the upper figure of FIG. 17, the ordinate axis represents a margin amount, and the abscissa axis represents an illumination system lens value. In the lower figure of FIG. 17, the ordinate axis represents a current density distribution minimum ratio, and the abscissa axis represents an illumination system lens value. The illumination system lens value is shown as a relative value to the lens value at which the total current amount is maximum. As shown in FIG. 17, it turns out that the current density distribution minimum ratio in the case of setting the lens value, at which the margin is maximum, on the illumination system lens is larger than that in the case of setting the lens value, at which the total current amount is maximum regardless of margin, on the illumination system lens. This means that uniformity of the current density is improved more in the case of setting the lens value, at which the margin is maximum, on the illumination system lens.

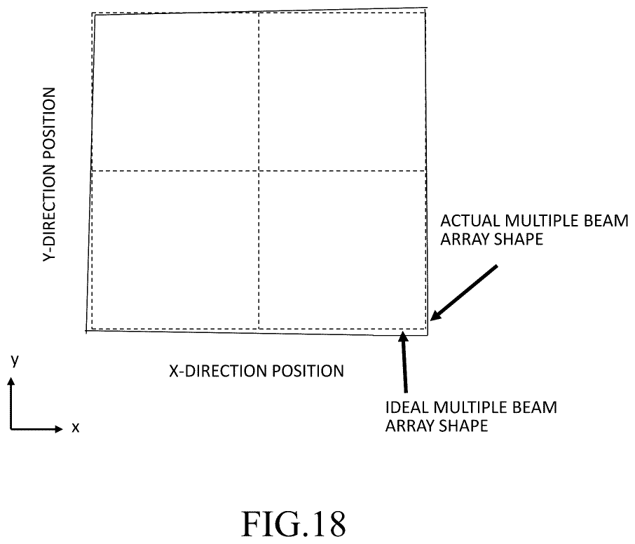

FIG. 18 is an illustration showing an example of a beam array shape on the surface of a target object according to the first embodiment. As shown in FIG. 18, the positional deviation of a beam locally occurred at one of the four corners of a beam array has been improved. Therefore, it turns out that a local beam distortion in the beam array has been prevented.

According to the comparative example, as shown in FIG. 9, even when a beam contacts the passage hole of the blanking aperture array mechanism, and a beam positional deviation is generated, by charging, on the surface of the target object, such a positional deviated beam is also detected by the Faraday cup 106. Therefore, there is no change in the total current amount even when such a local phenomenon occurs. In contrast, according to the first embodiment, a lens value at which the margin amount is large is selected. This means that the lens value, at which the total current amount is not easily reduced even if the positional relationship between the passage hole 25 of the blanking aperture array mechanism 204 and a beam is shifted, is selected. In other words, this indicates that all of the multiple beams 20, which are nearly parallel to each other, enter the passage hole 25 of the blanking aperture array mechanism 204 nearly perpendicularly (vertically), for example. Therefore, even if the positional relationship between the shaping aperture array substrate 203 and the blanking aperture array mechanism 204 is shifted, the total current amount can be maintained to be large. Thus, according to the first embodiment, it is possible to avoid the phenomenon as shown in FIG. 9 in which some of multiple beams collide with the wall surface of the passage hole 25 because of an incident angle being too oblique due to refraction by an illumination system lens. Therefore, local distortion of a beam array can be inhibited or reduced. Accordingly, local beam positional deviation and/or beam blur due to focus deviation can be inhibited or reduced.

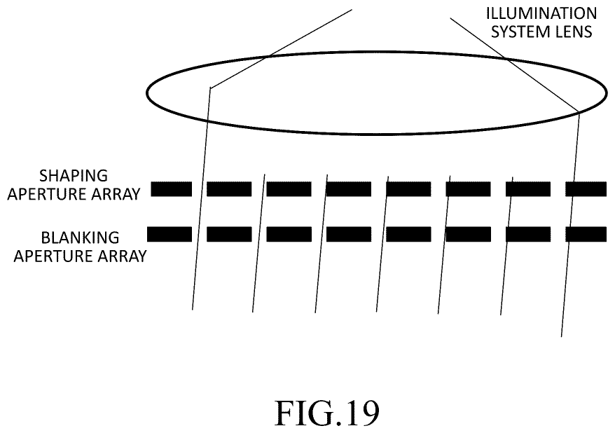

FIG. 19 is an illustration showing an example of beam illumination by an illumination system lens according to the first embodiment. FIG. 19 shows the case where all of the multiple beams 20 enter the passage hole of the blanking aperture array mechanism parallely and obliquely. This may occur when the illumination system lens is obliquely arranged. Even in such a case, according to the first embodiment, since the lens value at which all of the multiple beams 20 enter in parallel can be selected, it is possible to avoid local distortion and the like of the beam array described above.

After adjustment of the illumination lens 202 has been completed as described above, writing processing is executed. It will be specifically described.

In the writing step (S140), first, the rasterization processing unit 50 reads chip pattern data (writing data) from the storage device 140, and performs rasterization processing. Specifically, a pattern density (pattern area density) is calculated for each pixel 36.

Next, the shot data generation unit 52 calculates, for each pixel 36, a dose D with which the pixel 36 concerned is irradiated. For example, the dose D can be calculated by multiplying a preset base dose D_{base}, a proximity effect correction dose Dₚ, and a pattern area density ρ. The proximity effect correction dose Dₚ can be obtained as a relative value standardized by defining the base dose D_{base} to be 1. Thus, it is preferable to obtain the dose D to be in proportion to a pattern area density calculated for each pixel 36. With respect to the proximity effect correction dose Dₚ, the writing region (e.g., in this case, stripe region 32) is virtually divided into a plurality of proximity mesh regions (mesh regions for proximity effect correction calculation) by a predetermined size. The size of the proximity mesh region is preferably about 1/10 of the influence range of the proximity effect, such as about 1 μm. Then, writing data is read from the storage device 140, and, for each proximity mesh region, a pattern density ρ′ (pattern area density) of a pattern arranged in the proximity mesh region concerned is calculated.

Next, a proximity effect correction dose Dₚ for correcting a proximity effect is calculated for each proximity mesh region. Here, the size of the mesh region to calculate the proximity effect correction dose Dₚ does not need to be the same as that of the mesh region to calculate a pattern density ρ′. Furthermore, a correction model of the proximity effect correction dose Dₚ and its calculation method may be the same as those used in the conventional single beam writing system. The shot data generation unit 52 calculates, for each pixel 36, an irradiation time “t” of an electron beam for applying a calculated dose D to the pixel 36 concerned. The irradiation time “t” can be obtained by dividing the dose D by a current density J. Thereby, a dose map (actually, an irradiation time map) in which irradiation time data (shot data) for each pixel 36 is defined is generated.

In the case of performing multiple writing, a dose map (actually, an irradiation time map) is generated for each writing processing of each time of multiple writing. In other words, a dose map (actually, an irradiation time map) is generated for each stripe layer. The generated irradiation time data is stored in the storage device 142 in the order of shots.

Under the control of the writing control unit 72, using the illumination lens 202 on which the lens value acquired by the method described above is set, the writing mechanism 150 writes a pattern on the target object 101 by applying the multiple beams 20 having passed through a plurality of passage holes 25 of the blanking aperture array mechanism 204 to the target object 101.

As described above, according to the first embodiment, it is possible to achieve at least one of improving a current density distribution, reducing local beam distortion, reducing local beam blur, and reducing local position deviation.

Functions of processing described in each embodiment may be executed by a computer. A program for causing a computer to implement such functions of processing may be stored in a non-transitory tangible computer-readable storage medium such as a magnetic disk drive.

The lenses described in the Embodiment such as the illumination lens 202, the reducing lens 205, and the objective lens 207 are not limited to electromagnetic lenses, and may be electrostatic lenses or a combination of an electrostatic lens and an electromagnetic lens.

While the apparatus configuration, control method, and the like not directly necessary for explaining the present invention are not described, some or all of them can be appropriately selected and used on a case-by-case basis when needed. For example, although description of the configuration of the control unit for controlling the writing apparatus 100 is omitted, it should be understood that some or all of the configuration of the control unit can be selected and used appropriately when necessary.

Furthermore, any illumination lens adjustment method, multiple charged particle beam writing apparatus, and program that include elements of the present invention and that can be appropriately modified by those skilled in the art are included within the scope of the present invention.

Additional advantages and modification will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. An illumination lens adjustment method comprising:
setting variably a lens value of an illumination lens that leads multiple charged particle beams to a blanking aperture array mechanism, where a plurality of openings are formed, which individually performs blanking control for each beam of the multiple charged particle beams passing through the plurality of openings;
measuring a maximum movement amount for each the lens value from a reference positional relationship, while relatively moving a positional relationship between the multiple charged particle beams and the plurality of openings from the reference positional relationship in a range where a total current amount of beams passing through the plurality of openings for each the positional relationship is not less than a threshold; and
determining, using the maximum movement amount measured for each the lens value, the lens value of the illumination lens and outputting the lens value determined.

2. The method according to claim 1, further comprising:
illuminating, using the illumination lens, with a charged particle beam, a shaping aperture array substrate which is arranged between the illumination lens and the blanking aperture array mechanism and in which a plurality of openings are formed, wherein
the multiple charged particle beams are formed by letting portions of the charged particle beam individually pass through the plurality of openings in the shaping aperture array substrate.

3. The method according to claim 1, wherein the lens value of the illumination lens is determined using, as a parameter, only the maximum movement amount for each the lens value.

4. The method according to claim 1, further comprising:
measuring, for each the lens value and each the positional relationship, the total current amount of the beams passing through the plurality of openings in the blanking aperture array mechanism, wherein
the lens value of the illumination lens is determined using, as parameters, the maximum movement amount for each the lens value and the total current amount for each the lens value.

5. The method according to claim 1, further comprising:
measuring, for each the lens value, a current density distribution of the beams passing through the plurality of openings in the blanking aperture array mechanism, wherein
the lens value of the illumination lens is determined using, as parameters, the maximum movement amount for each the lens value, and a current density distribution minimum ratio, for each the lens value, which is a ratio of a minimum value to a maximum value acquired from the current density distribution measured.

6. The method according to claim 1, further comprising:
measuring, for each the lens value and each the positional relationship, the total current amount of the beams passing through the plurality of openings of the blanking aperture array mechanism; and
measuring, for each the lens value, a current density distribution of the beams passing through the plurality of openings of the blanking aperture array mechanism, wherein
the lens value of the illumination lens is determined using, as parameters, the maximum movement amount for each the lens value, the total current amount for each the lens value, and a current density distribution minimum ratio, for each the lens value, which is a ratio of a minimum value to a maximum value acquired from the current density distribution measured.

7. The method according to claim 2, wherein the positional relationship is moved by shifting a position of the blanking aperture array mechanism.

8. The method according to claim 2, wherein the positional relationship is moved by shifting a position of the shaping aperture array substrate.

9. A multiple charged particle beam writing apparatus comprising:
an emission source configured to emit a charged particle beam;
an illumination lens configured to refract the charged particle beam;
a shaping aperture array substrate in which a plurality of first openings are formed, configured to form multiple charged particle beams by being irradiated with the charged particle beam refracted by the illumination lens and letting portions of the charged particle beam individually pass through the plurality of first openings;
a blanking aperture array mechanism in which a plurality of second openings are formed, configured to individually perform blanking control for each beam of the multiple charged particle beams passing through the plurality of second openings;
a moving mechanism configured to relatively move the shaping aperture array substrate and the blanking aperture array mechanism;
a current amount measurement mechanism configured to measure a total current amount of beams passing through the plurality of second openings;
a stage configured to mount thereon a target object on which a pattern is written by irradiation with the beams passing through the plurality of second openings;
a setting circuit configured to variably set a lens value of the illumination lens;
a movement amount measurement circuit configured to measure a maximum movement amount for each the lens value from a reference positional relationship, while relatively moving a positional relationship between the shaping aperture array substrate and the blanking aperture array mechanism from the reference positional relationship in a range where the total current amount of the beams passing through the plurality of second openings for each the positional relationship is not less than a threshold; and
a determination circuit configured to determine, using the maximum movement amount measured for each the lens value, the lens value of the illumination lens.

10. A non-transitory computer-readable storage medium storing a program for causing a computer to execute processing comprising:
setting variably a lens value of an illumination lens which leads multiple charged particle beams to a blanking aperture array mechanism, where a plurality of openings are formed, which individually performs blanking control for each beam of the multiple charged particle beams passing through the plurality of openings;
measuring a maximum movement amount for each the lens value from a reference positional relationship, while relatively moving a positional relationship between the multiple charged particle beams and the plurality of openings from the reference positional relationship in a range where a total current amount of beams passing through the plurality of openings for each the positional relationship is not less than a threshold;
storing the maximum movement amount measured for each the lens value in a storage device; and
reading the maximum movement amount for each the lens value stored in the storage device, and determining the lens value of the illumination lens by using the maximum movement amount read for each the lens value, and outputting the lens value determined.
